(19) United States
(12) Patent Application Publication
(10) Pub. No.: US 2013/0194881 A1
(43) Pub. Date: Aug. 1, 2013

(54) AREA-EFFICIENT MULTI-MODAL SIGNALING INTERFACE

(71) Applicants: Steven C. Woo, Saratoga, CA (US); Amir Amirkhany, Sunnyvale, CA (US); Catherine Chen, Cupertino, CA (US); David Secker, San Jose, CA (US); Jie Shen, Fremont, CA (US)

(72) Inventors: Steven C. Woo, Saratoga, CA (US); Amir Amirkhany, Sunnyvale, CA (US); Catherine Chen, Cupertino, CA (US); David Secker, San Jose, CA (US); Jie Shen, Fremont, CA (US)

(21) Appl. No.: 13/878,419

(22) PCT Filed: Nov. 7, 2011
(86) PCT No.: PCT/US11/59644

§ 371 Date: Apr. 8, 2013

Related U.S. Application Data
(60) Provisional application No. 61/411,843, filed on Nov. 9, 2010.

(51) Int. Cl. G11C 7/00

(52) U.S. Cl. CPC G11C 7/00
USPC 365/191

(57) ABSTRACT

One or more pins may be modally assigned to either the command/address (C/A) or data (DQ) blocks of a uniform-package, multi-modal PHY (physical signaling interface) of a memory controller, thus enabling those pins to be used as C/A pins when the PHY is connected to some memory types, and as DQ pins when the PHY is connected to other memory types.

### CROSS-REFERENCE TO RELATED APPLICATIONS

This application hereby claims priority to and incorporates by reference U.S. Provisional Application No. 61/411,843, filed Nov. 9, 2010 and entitled “AREA-EFFICIENT MULTI-MODAL PHYSICAL SIGNALING INTERFACE.”

### TECHNICAL FIELD

The disclosure herein relates generally to integrated circuit memory technology and more particularly to signaling interfaces in memory system components.

### BRIEF DESCRIPTION OF THE DRAWINGS

The various embodiments disclosed herein are illustrated by way of example, and not by way of limitation, in the figures of the accompanying drawings and in which like reference numerals refer to similar elements and in which:

FIG. 1A illustrates an exemplary layout of a multi-mode controller signaling interface having two 16-link data blocks distributed on either side of a command/address block;

FIG. 1B illustrates exemplary signal counts for different memory types that may be supported by the multi-mode signaling interface of FIG. 1A;

FIG. 2 illustrates a possible mapping of signals between different operating modes in an exemplary multi-modal signaling interface;

FIG. 3 illustrates an extension of the multi-modal arrangement of FIG. 2 to a third operating mode that supports additional data links;

FIGS. 4A and 4B illustrate alternative embodiments of physical signaling interfaces that provide multi-modality in a uniform package while avoiding substantial increase in area consumption that otherwise limits adoption of differential signaling or other modes that expand the number of data interconnects;

FIG. 5 illustrates embodiments of modal I/O circuits that may be used to implement a pair of interconnects, A and B within a uniform-package multi-modal physical signaling interface according to FIG. 4A or 4B; and

FIG. 6 illustrates an embodiment of mode control logic that may be employed within a memory controller to enable configuration of multi-mode signaling interfaces as shown, for example, in FIGS. 4A and 4B.

### DETAILED DESCRIPTION

The rising cost of processor development results in the desire to utilize processor designs across as many product segments as possible. However, different memory types may be used across these product segments to better match performance, cost, and capacity requirements for these segments. One solution is to manufacture different processors for each segment, each with different memory interfaces or “PHYs” (physical signaling interfaces). Coupled with long development times that make predicting DRAM price points and DRAM availability difficult at the time systems are manufactured and sold, it can be difficult for processor manufacturers to start the right mix of wafers (each with processors that connect to different memory types) to adequately meet the needs of the market that far ahead in time.

Multi-modal PHYs, which can communicate with multiple memory types, mitigate risk by allowing different memory types to be connected to the same processor. They are used in several applications in the compute, consumer, and graphics markets. Multi-modal PHYs allow a system designer to match DRAM price and availability to the needs of the various product segments supported by the processor, and to mitigate price and availability risk for new memory types during memory transitions. They also allow processors to be speed binned, with the fastest processors connecting to the highest performance memory, and being put into the highest performance end systems. Although a processor (or other control IC) having a multi-modal PHY may be packaged in various different packages each according to intended application, additional benefits result when the multi-modal PHY is implemented within a single package that supports multiple memory types (i.e., multi-modal PHY with no package changes or “uniform package” multi-modal PHY). Manufactured in this manner, the resulting processor can be paired with memory at the time of final system manufacture, thus enabling the same multi-modal-PHY package to be designed into a system well before the memory type determination is made. This flexibility and support for late-stage memory-type selection (e.g., determined at system assembly time), reduces the need to estimate customer demand and thus reduces inventory risks. That is, the uniform-package multi-modal PHY obviates estimation of (or commitment to) a particular memory type at packaging time, thus avoiding the increased demand estimation and inventory risk that the longer lead time would otherwise incur, and instead allowing market needs to be assessed closer to when the systems will be sold.

While multi-modal PHYs provide flexibility, that flexibility comes at a cost of potentially increased die or package area consumption, an increase that may not be feasible in some area-constrained packaging or die-interconnect technologies. For example, the limited interconnect area in flip-chip packages tends to be entirely consumed by bumps required for the PHY, thus forcing designers to settle for less flexible PHY options. Further, the area increase tends to be particularly significant if both single-ended and differential signaling are supported, all of which raises the question of how to achieve the flexibility afforded by multi-modal PHYs while at the same time addressing PHY area concerns.

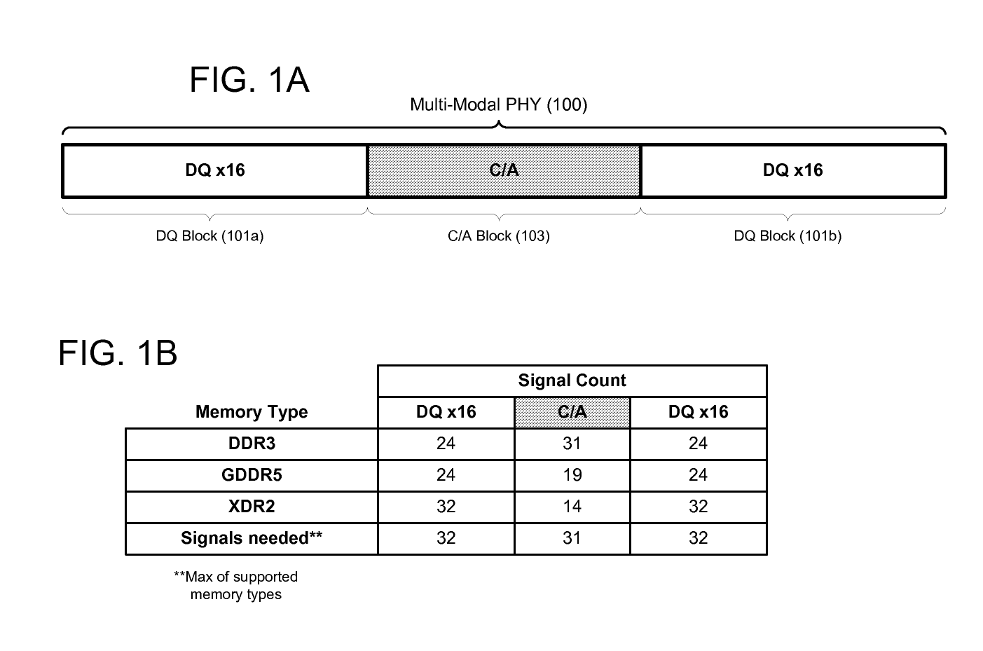

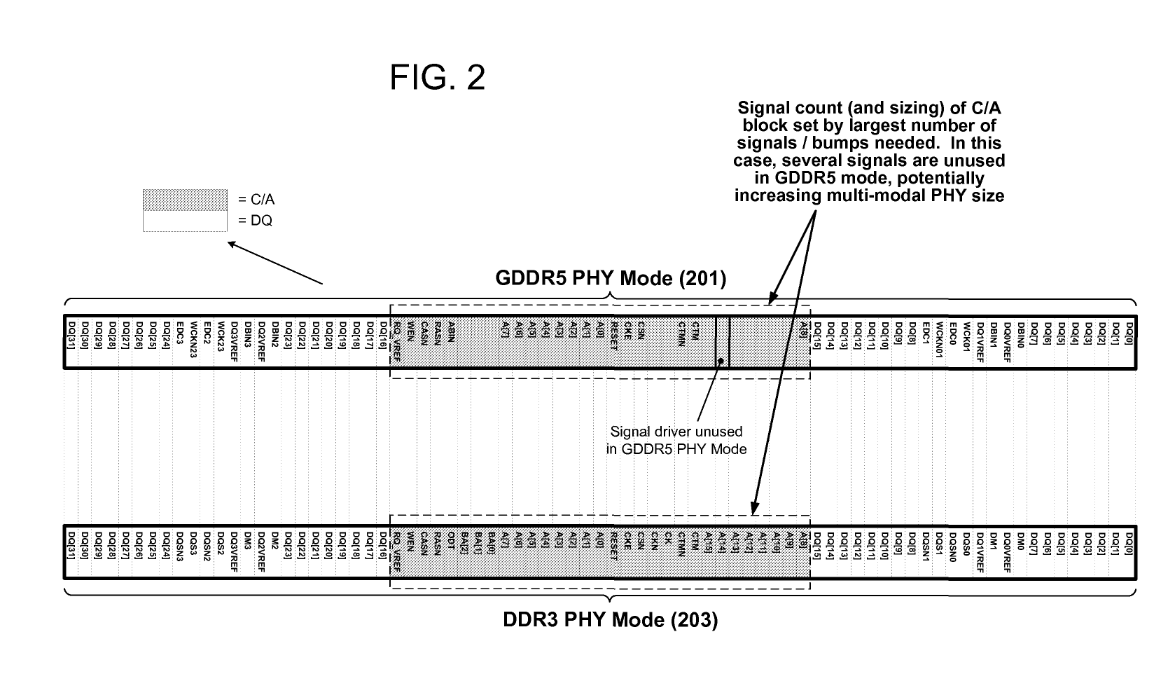

Multi-modal PHYs typically are broken into a command/address (C/A) block (i.e., for all Command/Address signals) and one or more DQ blocks (i.e., for all data signals). The sizes of these blocks are set by the number of bumps required by the mode requiring the most bumps. For example, in a PHY that supports GDDR5 and DDR3, a typical graphics x32 implementation may require 31 pins in the C/A block, and 48 pins in the DQ blocks. FIG. 1A illustrates a generalized embodiment of a x32 (i.e., 32 data link) multi-mode controller PHY 100 having two 16-link DQ blocks 101a, 101b distributed on either side of a C/A block 103. The C/A block is shaded to distinguish it from the DQ blocks, a convention carried forward in other Figures below. Signal count in each block is an important and often dominant factor in determining the required PHY area. FIG. 1B illustrates exemplary signal counts for DDR3, GDDR5 and XDR2 memory types that may be supported by the multi-mode PHY of FIG. 1A.

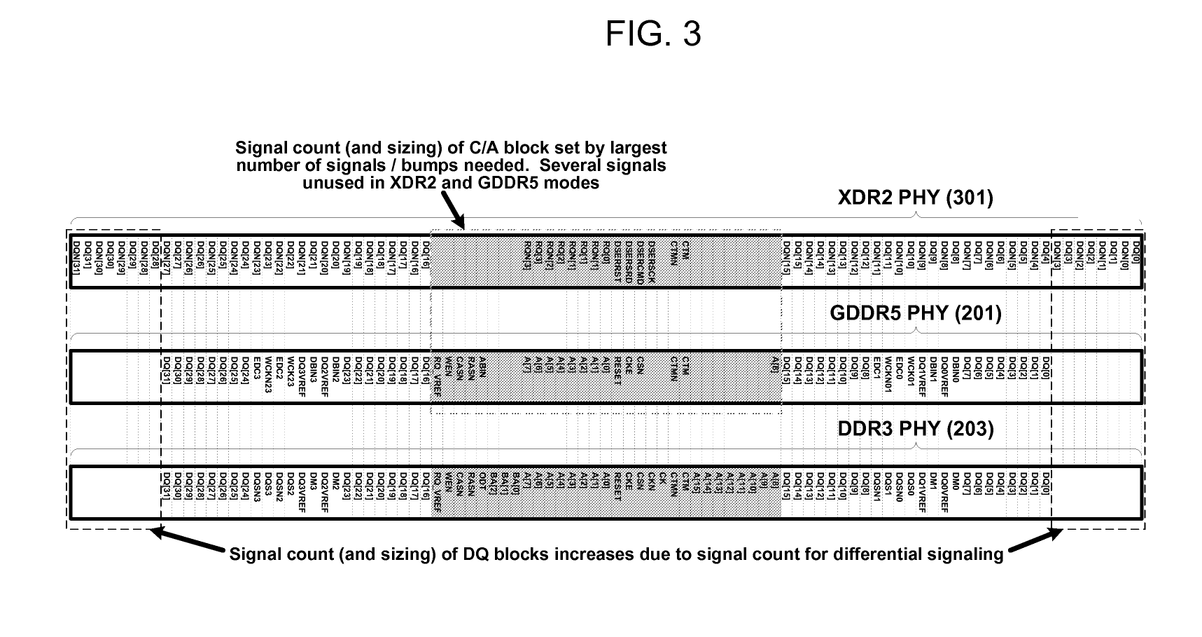

FIG. 2 illustrates one possible mapping of signals between the GDDR5 and DDR3 operating modes (201 and 203, respectfully) in an exemplary multi-mode PHY. As shown, the C/A block (shaded) includes the larger of the number of signals needed for the GDDR5 and DDR3 modes. In this case, DDR3 has the largest number of C/A signals so that, when applied in a GDDR5 memory system, several of the C/A signals are unused so that the corresponding signal output driver is unused.

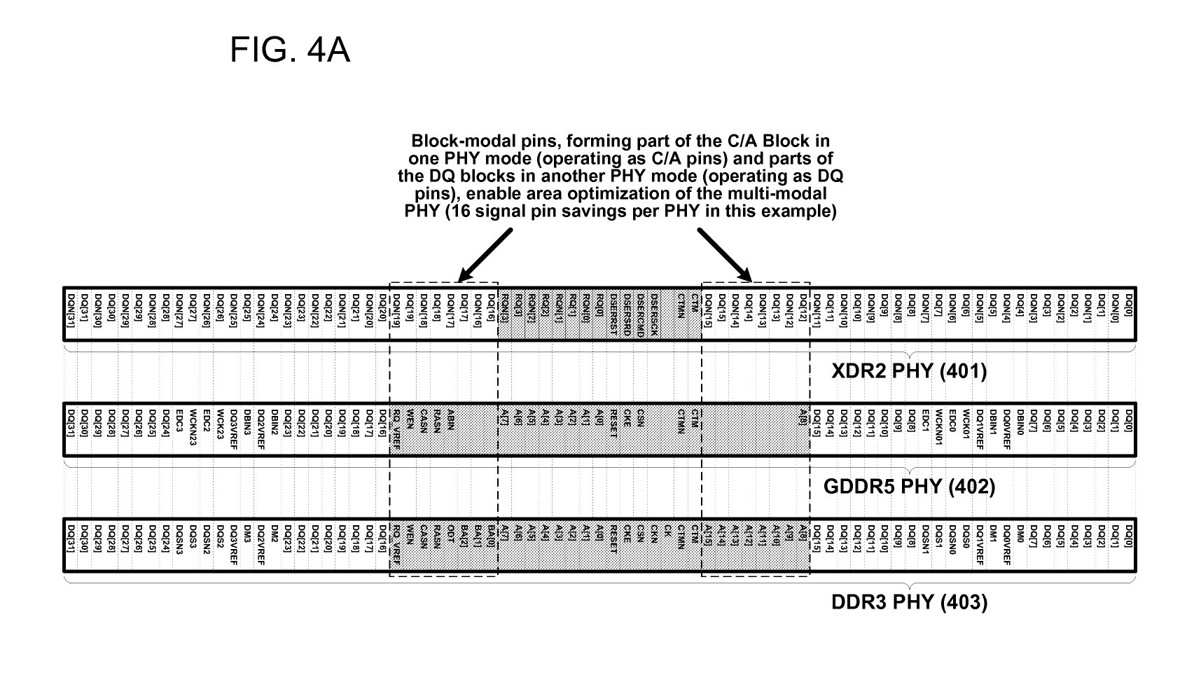

Supporting differential signaling on the DQs (which allows higher per-pin data rates to be achieved) requires two signal conductors per data link, and thus may increase the number of signal pins in the DQ blocks compared to DRAMs that use single-ended signaling. The above 32 DQ link PHY, for example, would require at least 64 signal interconnects in the DQ blocks. Thus, following the approach shown in FIG. 2 in a multi-modal PHY that supports XDR2 memory (i.e., a differential DQ memory), in addition to DDR3 and GDDR5 memories, would further increase the size of the PHY by 16 signal pins as shown in FIG. 3. More specifically, in the XDR2 example shown at 301, the support for differential signaling increases the area for the DQ blocks (eight extra signal interconnects per block), thus increasing the overall PHY area. Moreover, the area penalty incurred by the uniform-package multi-modal PHY area is multiplied by the total number of memory channels. In a graphics card that supports 8 memory channels, for example, an additional 128 signal pins are required to support differential-signaling XDR2 memory, an increase that may consume an unacceptable amount of area in many applications.

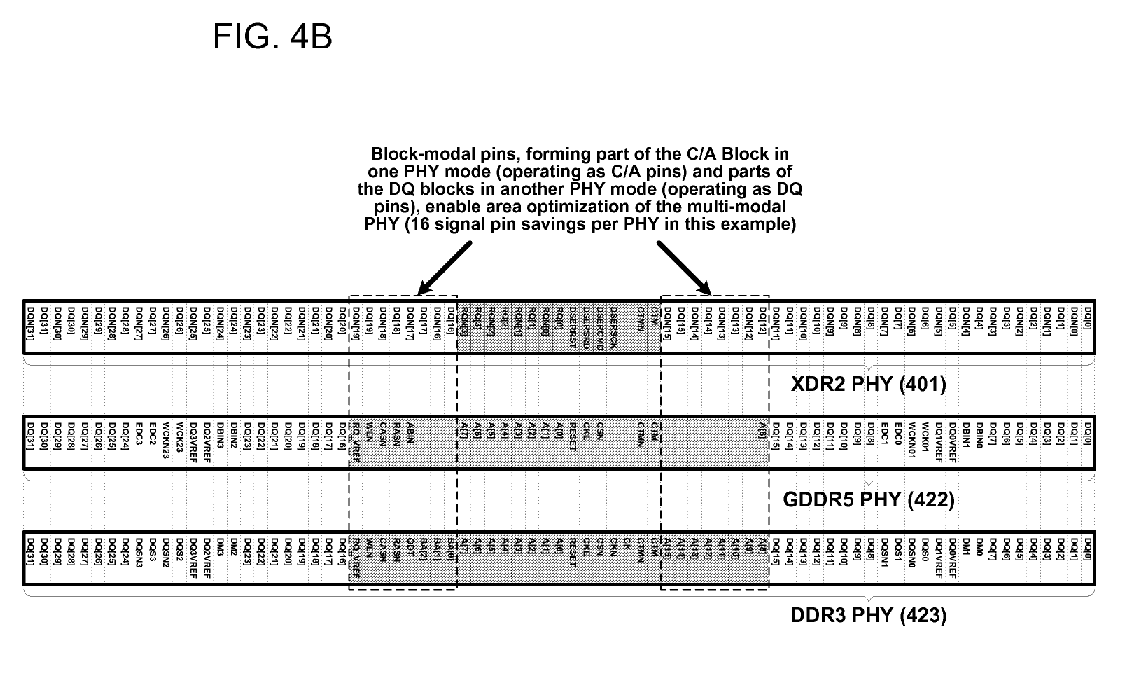

FIGS. 4A and 4B illustrate alternative PHY embodiments that provide multi-modality in a uniform package (i.e., without package changes) while avoiding substantial increase in area consumption that otherwise limits adoption of differential signaling or other PHY modes that expand the number of data interconnects.

As shown in each figure, a number of pins otherwise dedicated to the C/A block may instead be modally assigned to either the C/A or DQ blocks. Consequently, such “block modal” or “multi-block” pins may be used as C/A pins when the PHY is connected to some memory types, and as DQ pins when the PHY is connected to other memory types, thus enabling selected pins (or any other type of signal-link interconnect) to be allocated alternately to a command/address signaling function or a data signaling function according to the interface configuration. In the particular embodiment shown, for example, a uniform-package, multi-modal PHY includes sixteen block-modal pins that enable support for XDR2 memory (16 Gbps differential signaling) as well as GDDR5 and DDR3 modes (401, 402, 403, respectively) without increasing the total interconnect area beyond that required to support DDR3 alone. Thus, allowing some pins to be modally assigned as C/A pins of one DRAM and/or signaling type in a first mode (e.g. DDR3 and GDDR5 modes) and as DQ pins of another DRAM/signaling type in a second mode (e.g. XDR2 mode) enables I/O count to be reduced in a multi-modal PHY supporting multiple signaling types. More generally, the block modal pins enable area-efficient (i.e., reduced area) implementation of a multi-modal, uniform-package PHY having increased data-pin count mode (e.g., differential signaling mode). For example, while the embodiment depicted in FIG. 4A shows advantages for a uniform-package multi-mode PHY supporting XDR2, GDDR5, and DDR3 memory types, similar advantages may be achieved for processors or other control components that support additional and/or alternative DRAMs and signaling types. Note that the C/A pins may be limited to uni-directional signaling modes (e.g., with C/A signals flowing uni-directionally from the multi-modal PHY to one or more attached memory components or other recipient integrated circuit devices, in contrast to bi-directional data signaling links) in some embodiments and may be operated bi-directionally in other embodiments. In bi-directional embodiments, for example, C/A pins may be used at certain times and/or in particular configurations to receive test signals or other types of information sent from one or more attached integrated circuit devices to the multi-modal PHY.

In contrast to the PHY modes shown in FIG. 4A, all interconnect pairs used to transmit and/or receive differential signals in the PHY modes shown in FIG. 4B (i.e., for each supported memory type which, in this example, includes GDDR5, DDR3 and XDR2) are disposed side by side rather than being separated by one or more other signal interconnects. For example, in the GDDR5 PHY mode 422, the component signals of each differential write clock (i.e., component signals WCK23 and WCKN23 in one instance, and component signals WCK12 and WCKN12 in another) are output via side-by-side (physically adjacent) interconnects. Similarly, in the DDR3 PHY mode 423, the component signals of each differential data strobe (i.e., component signals DQS0 and DQSN0, DQS1 and DQSN1, DQS2 and DQSN2, and DQS3 and DQSN3) are transmitted and received via side-by-side interconnects. Also, in the embodiment of FIG. 4B, the differential signal mapping is aligned from PHY mode to PHY mode (to the extent possible) so that a given pair of interconnects may be dedicated to conveying a differential signal in each supported PHY mode. That is, differential signals that appear in each supported memory type (DDR3, GDDR5, and XDR2 in the example shown) are mapped to the same pair of interconnects.

Mapping differential signal components to side-by-side interconnects and aligning the differential signal mapping within supported memory types to the same pair of interconnects may improve on-chip and off-chip signal routing and interconnection in a number of ways. For example, the constituent signals of each differential signal pair may be efficiently routed side by side on-chip (i.e., on an integrated circuit die) between their respective pins (or other external-interface contacts) and a differential driver, receiver or transceiver. Similarly, the side-by-side disposition of differential interconnects facilitates side-by-side pin connection and routing of the constituent signal lines of a chip-to-chip differential signaling link (i.e., a pair of conductors formed between IC dice through intra-package connections such as bond wires, cables or the like, or, in the case of separately packaged IC dice, through package-to-package signal paths formed by traces and vias on a printed circuit board, cables, etc.), potentially improving signal integrity on the differential link by reducing cross-talk, timing skew, etc. Moreover, dedicating a given pair of interconnects to a differential signaling function in each supported PHY mode (and thus for each supported memory type) may simplify the logical interface between the controller core and PHY as only one incoming and/or outgoing signal source need be communicated between the core and the PHY with respect to the pair of interconnects, regardless of the selected PHY mode.

Reflecting on FIGS. 4A and 4B, it should be noted that a number of the signals shown may be optional within a given PHY mode and thus may be omitted in alternative embodiments. For example, the four reference-voltage interconnects allocated within the GDDR5 and DDR3 PHY modes (402, 403, 422 and 423), DQ0VREF-DQ3VREF, may be omitted in embodiments in which the controller component is designed to use an internally generated reference voltage instead of receiving voltage references from an external source.

Also, still referring to FIGS. 4A and 4B, while command and address interconnects have generally been described as belonging to a single command/address signaling category, these signals may also be viewed as forming separate physical or logical blocks in a given PHY mode. That is, address interconnects are generally used to transmit address signals that specify one or more memory devices within a larger set of memory devices (e.g., a rank-select or chip-select signal) and/or a memory location within the specified memory devices (e.g., bank, row, column address values, though alternative addressing hierarchies may apply according to the memory core technology), while command signals are used to specify an operation to be carried out within the specified memory device(s) (e.g., row activation, column read, column write, precharge, refresh, calibration or other maintenance, etc., though various other operations may be specified in accordance with the memory core technology). In some cases, one or more interconnects dedicated to address signaling in one PHY mode may be used instead for command signaling in another PHY mode. Moreover, those same interconnects or any of them may be dedicated to single-ended or differential data signaling (e.g., conveyance of write data to be stored in specified memories and/or read data retrieved from specified memories) in yet another PHY mode. More generally, signaling interfaces that support multiple signaling types and modal CA/DQ interconnects may apply those signaling types and modal pins to communicate directly to memory components (e.g., DRAMS) for some signaling types, and to communicate to other types of integrated circuit devices for other signaling types. For example, a signaling interface that supports multiple signaling types and modal CA/DQ interconnects may communicate in at least one configuration to a buffer IC that is itself coupled via one or more other signaling interfaces to other integrated circuit devices (e.g., DRAMS, other processors, ASICs, etc.) in a chip-to-chip interconnection. As a more specific example, modal CA/DQ pins within a multi-modal signaling interface may be applied to effect a relatively wide, single-ended RQ interface for communication with DDR3 or DDR4 memory ICs in a first PHY mode, or applied in a differential signaling PHY mode to communicate with a memory buffer (e.g., on a memory module or motherboard), or even to function as a chip-to-chip interface for communicating with another processor or other type of integrated circuit device. By this arrangement, a single signaling interface may be used to communicate with unbuffered memory modules (e.g., for the desktop or small server market) as well as to buffered memory modules (e.g., for medium and larger server markets). Further, the different signaling types described may be applied to support direct connection to memory components (e.g., single-ended signaling to DDR3 and DDR4 memory components), as well as chip-to-chip interfaces to other integrated circuit devices (e.g., differential signaling with respect to another processor, ASIC, buffer, etc.).

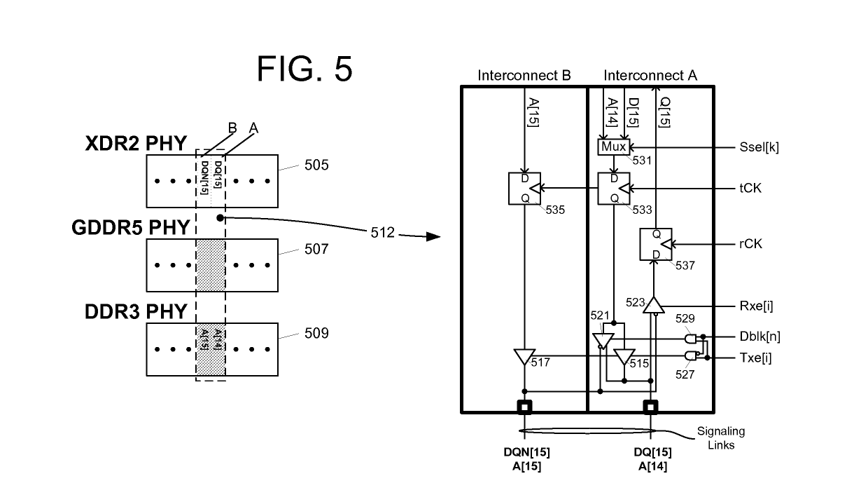

FIG. 5 illustrates embodiments of modal I/O circuits (i.e., input and/or output circuits) that may be used to implement pair of interconnects, A and B (e.g., at pins, solder bumps, microballs, pads, etc., of an IC die or IC package), within a uniform-package multi-modal PHY. In the particular example shown, the interconnect pair is tri-modal, having one of three different I/O modes 505, 507, 509 according to the selected PHY mode. More specifically, if an XDR2 PHY mode 505 is selected, the interconnects serve as differential data I/O driver for data links DQ[15] and DQN[15] and thus form part of a PHY data block. By contrast, if DDR3 PHY mode 509 is selected, the interconnects serve as command/address drivers (and specifically address drivers) for C/A links A[14] and A[15] and thus form part of the PHY C/A block. If GDDR5 mode 507 is selected, the interconnects are unused and thus may be disabled to save power. In alternative embodiments, more or fewer than three signaling modes may be selected, depending upon the memory types to be supported.

Referring to detail view 512, the A and B interconnects include respective single-ended output drivers 515, 517, and interconnect A additionally includes differential output driver 521 and differential receiver 523. The single-ended output drivers 515, 517 are enabled by logic gate 527 to transmit address data bits A[15] and A[14] on respective C/A links when the PHY mode specifies that the interconnects are transmit-enabled (i.e., Txe[i] is asserted) and form part of the C/A block (i.e., Dblk[n] is deasserted), and thus when DDR3 PHY mode is selected. By contrast, the differential output driver 521 is enabled by logic gate 529 to transmit write data bit, D[15], differentially via DQ links DQ[15] and DQN[15] when the PHY mode specifies that the interconnects are transmit-enabled and form part of the data block (i.e., Txe[i] and Dblk[n] both asserted), and thus during data transmit operations when XDR2 PHY mode is selected. A multiplexer 531 or other selector circuit is provided within interconnect A to select either DQ[15] or A[14] to be supplied to an output register 533 (or latch) according to the state of a signal-select input (Ssel[k]), and thus according to the selected PHY mode. Note that Dblk[n] may alternatively be used to control the multiplexer selection and thus reduce the number of control signals required, at least for the pair of interconnects shown. A transmit clock signal (tCK), which may have a frequency in accordance with the selected PHY mode, is supplied to time the data or address-bit load operation within output register 533 and in counterpart output register 535 within interconnect B. Though not shown, circuitry may be provided to gate the transmit clock and/or disable data-load operations within either or both of the output registers during intervals or PHY modes in which no signals are to be transmitted at either or both interconnects.

The differential receiver 523 is enabled to receive read data bit, Q[15], via DQ links DQ[15] and DQN[15] when the PHY mode specifies that the interconnects are receive-enabled, and thus during data receive operations in the XDR2 PHY mode. In the embodiment shown, the differential receiver outputs a logic-level signal that is captured within a receive data register 537 (i.e., a read data register in this example) in response to transitions of a receive clock signal, rCK. As with the signal transmission path, circuitry may be provided to gate the receive clock and/or disable data capture within receive data register 537 during intervals or PHY modes in which no signals are to be received at the interconnects.

It should be noted that various aspects of the interconnects shown in FIG. 5 may be changed in alternative embodiments. For example, additional multiplexers may be presented to select the outputs of individual signal drivers (i.e., choosing between the single-end and differential output drivers, instead of tri-state coupling the output drivers), and various different control logic arrangements may be used to enable and disable the various drivers and registers shown and to control the multiplexer selection. Thus, the detail view of FIG. 5 should be understood as a conceptual view of the particular interconnect pair shown, and in no way limiting the various alternative arrangements that may be used.

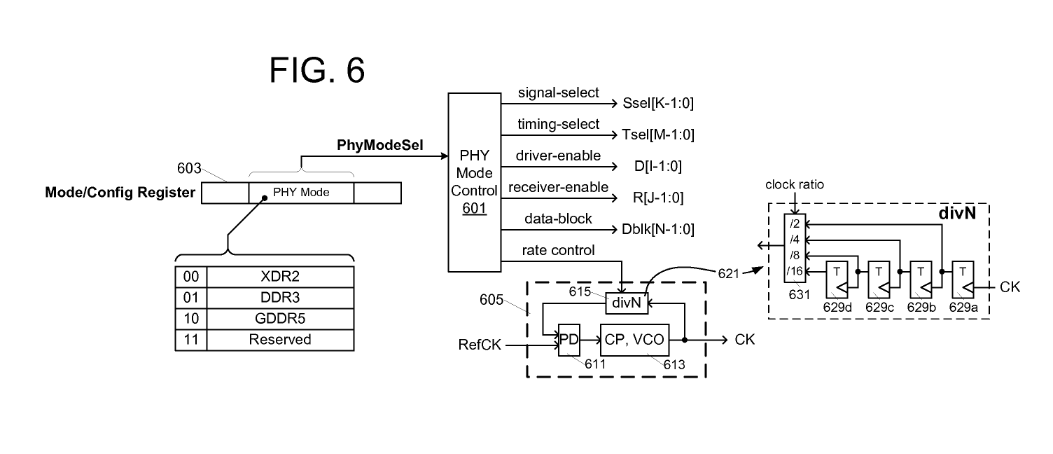

FIG. 6 illustrates an embodiment of a PHY mode controller 601 that may be employed within a memory controller to enable configuration of multi-mode signaling interfaces as described, for example, in reference to FIGS. 4A and 4B. As shown, PHY mode controller 601 receives a PHY mode value (“PhyModeSel”) from a mode register 603 (or configuration circuit, or combination of registers and/or configuration circuits, any and all of which may be programmed by an external device to establish a desired PHY mode) and outputs various control signals in response. In the particular embodiment shown, PHY mode controller 601 outputs signal-select signals, timing-select signals (e.g., for selecting between different event timing sources such as clocks, strobes, etc. to be applied within various interconnects of the PHY), driver-enable signals, receiver-enable signals, data-block signals and so forth, which may be applied, for example and without limitation, as shown in FIG. 5. Thus, if the PHY mode value specifies an XDR2 mode, the PHY mode controller raises signal-select Ssel[k] to select D[15] as the transmit signal source, and also raises data-block signal Dblk[n] to enable differential signal transmission and reception. The driver-enable signal and receiver-enable signals (D[i] and R[j]) are also raised and, for example, gated with operational signals to assert the above-described receive-enable signal (Rxe) and transmit-enable signal (Txe) during data receive and transmit operations, respectively. Continuing the example with reference to FIGS. 5 and 6, if the PHY mode value specifies a DDR3 mode, the PHY mode controller lowers Ssel[k] to select A[14] as the transmit signal source within interconnect A, lowers DBlk[n] to enable the single-ended-signal drivers within both interconnects, and lowers the receiver-enable signal to disable the differential receiver. As in XDR2 PHY mode, the driver-enable signal may be gated with one or more operational signals to assert the transmit-enable signal during command/address transmit intervals. In GDDR5 mode, the interconnects are unused, so that PHY mode controller 601 responds to the GDDR5 mode selection by lowering the driver-enable and receiver-enable signals to disable the interconnects. Though not specifically shown, additional circuitry may be provided to suppress clocking (or otherwise disable load operations) within the various registers of the interconnects when the interconnects are unused (e.g., when the driver-enable and receiver-enable signals are deasserted).

Still referring to FIG. 6, PHY controller 601 may also output a rate-control signal to establish one or more signaling rates within the PHY in accordance with the selected PHY mode. In the embodiment shown, for example, a PLL 605 formed by a phase detector 611, voltage controlled oscillator 613 (including a charge pump or other control-voltage filter), and selectable-divisor clock-divider circuit 615 is provided to establish a variable-rate clock signal that may be applied within one or more interconnects of the PHY, for example, as transmit and/or receive clock signals (tCK, rCK). In one embodiment, shown for example at 621, the selectable-divisor clock-divider circuit includes a sequence of toggle flip-flops 629a-629d to divide the output clock, CK, by a value of 2, 4, 8 or 16 (more, fewer, and/or different divisor values may be selected in alternative implementations) to establish an output clock rate that is 2, 4, 8 or 16 times the frequency of a reference clock (i.e., a clock generated within the control component or received from an external source and phase-locked to the frequency-divided feedback clock output from clock-ratio multiplexer 631) and thus provide a clock having a mode-specific frequency within the PHY.

PHY mode controller 601 may provide a variety of control outputs in addition to or as alternatives to those shown. For example, the PHY mode controller may select between multiple different reference clock frequencies, signal transmission formats (e.g., bit steering, bit stuffing), power control and so forth in accordance with the specified PHY mode. In one embodiment, for example and without limitation, PHY mode controller 601 may select the clock multiplier ratio in another PLL (e.g., selecting the feedback clock frequency divisor), select one of multiple reference clock sources (including selecting between internal and external reference clock sources) and/or control the operation of the reference clock oscillator itself (e.g., switchably controlling the number of stages in a ring oscillator). With regard to signal transmission formats, PHY mode controller 601 may assert signals as necessary to steer bits to specific interconnects, perform bit-stuffing operations (e.g., insertion of dummy bits or other non-information bits into the bitstream output from a given interconnect), provide framing control, perform error-checking/correction and so forth. The PHY mode controller may also output signals as necessary to avoid unnecessary power consumption, including disabling clock generation sources that are unnecessary for a given PHY mode and/or dynamically switching clocking sources or other power-consuming circuitry between active and low-power states in response to detected events or conditions, and/or when externally instructed to do so. Also, to provide flexibility and support for future PHY requirements, any or all of the various control vectors output by the PHY mode controller (e.g., signal-select, timing-select, driver-enable, receiver-enable, data-block, rate control, etc.) may be independently controlled by settings within one or more mode registers and/or configuration circuits instead of being logically derived from the specification of a particular memory type. More generally, selection of any of the supported PHY modes within embodiments presented herein may be accompanied by a change in various aspects of the overall signaling protocol including without limitation, changes in data formatting and/or encoding (e.g., burst length, interface width, error encoding, transition-density encoding, etc.), command formatting and/or encoding, signaling rate (including different signaling rates as between different classes of signals with, for example, command signals and/or address signals being transmitted at a lower or otherwise different signaling rate than data signals), sample point control (e.g., strobe-based vs. sampling in response to an internally generated or recovered clock), support for data masking, reference voltage generation, signal inversion and so forth.

A number of advantages and benefits may be achieved by providing a control component operable to interface to at least two types of memory devices having different control/address interfaces, where a portion of the control/address interface of the memory controller is reconfigured as a data interface for one of the two memory types to account for the different control address interface. Such benefits include, but are not limited to:
Flexibility of multi-modal PHYs with no package changes.
Reduced area overhead for supporting multiple DRAM types, including XDR, XDR2 that use differential signaling.
May use surplus modal C/A pins to support ECC or other signaling functions for one or more memory types (not limited to selection between DQ and CA modes).
May be used in virtually any IC device having a memory control function including, without limitation, memory controllers, processors (including general purpose processors (CPUs), graphics processors (GPUs), signal processors, etc.), application-specific integrated circuits (ASICs), and so forth.

It should be noted that the various circuits and physical signaling interfaces (PHYs) disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and VHDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, computer storage media in various forms (e.g., optical, magnetic or semiconductor storage media, whether independently distributed in that manner, or stored “in situ” in an operating system).

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present disclosed embodiments. In some instances, the terminology and symbols may imply specific details that are not required to practice those embodiments. For example, any of the specific numbers of bits, signal path widths, signaling or operating frequencies, component circuits or devices and the like may be different from those described above in alternative embodiments. Additionally, links or other interconnection between integrated circuit devices or internal circuit elements or blocks may be shown as buses or as single signal lines. Each of the buses may alternatively be a single signal line, and each of the single signal lines may alternatively be buses. Signals and signaling links, however shown or described, may be single-ended or differential. A signal driving circuit is said to “output” a signal to a signal receiving circuit when the signal driving circuit asserts (or deasserts, if explicitly stated or indicated by context) the signal on a signal line coupled between the signal driving and signal receiving circuits. The term “coupled” is used herein to express a direct connection as well as a connection through one or more intervening circuits or structures. Integrated circuit device “programming” may include, for example and without limitation, loading a control value into a register or other storage circuit within the device in response to a host instruction (and thus controlling an operational aspect of the device and/or establishing a device configuration) or through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The terms “exemplary” and “embodiment” are used to express an example, not a preference or requirement.

Various modifications and changes may be made to the embodiments presented herein without departing from the broader spirit and scope of the disclosure. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

What is claimed is:

1. A memory controller comprising:
a plurality of signaling-link interconnects to be connected to respective external signaling links; and
configuration logic to allocate a first number of the signaling-link interconnects to a data signaling function and a second number of the signaling-link interconnects to a command/address signaling function in a first interface configuration, and to allocate a third number of the signaling-link interconnects to the data signaling function and a fourth number of the signaling-link interconnects to the command/address signaling function in a second interface configuration, the third number of the signaling-link interconnects being greater than the total number of signaling-link interconnects minus the second number of signaling-link interconnects.

2. The memory controller of claim 1 wherein the configuration logic to allocate the first number of the signaling-link interconnects to the data signaling function in the first interface configuration and to allocate the third number of the signaling-link interconnects to the data signaling function in the second interface configuration comprises circuitry to enable at least a portion of the first number of the signaling-link interconnects to output a corresponding number of single-ended write-data signals onto respective single-ended signaling links in the first interface configuration and to enable at least a portion of the third number of the signaling-link interconnects to output differential write-data signals onto respective differential signaling links in the second interface configuration.

3. The memory controller of claim 1 wherein the configuration logic to allocate the second number of signaling-link interconnects to the command/address signaling function and to allocate the third number of signaling links to the data signaling function comprises circuitry to limit the second number of signaling-link interconnects to uni-directional signaling in the first interface configuration and to enable at least a portion of the second number of signaling-links to bi-directionally transmit write-data and receive read data in the second interface configuration.

4. The memory controller of claim 1 wherein the configuration logic comprises a register to store a value that indicates one of a plurality of interface configurations, the plurality of interface modes including at least the first interface configuration and the second interface configuration.

5. The memory controller of claim 1 wherein the third number of signaling-link interconnects and the fourth number of signaling-link interconnects collectively constitute more signaling-link interconnects than collectively constituted by the first number of signaling-link interconnects and the second number of the signaling-link interconnects.

6. The memory controller of claim 1 wherein the configuration logic comprises circuitry to allocate a fifth number of the signaling-link interconnects to the data signaling function and a sixth number of the signaling-link interconnects to the command/address signaling function in a third interface configuration, wherein the third number of the signaling-link interconnects is greater than the total number of signaling-link interconnects minus the fifth number of signaling-link interconnects.

7. The memory controller of claim 6 wherein the fifth number of signaling-link interconnects and the sixth number of signaling-link interconnects collectively constitute more signaling-link interconnects than collectively constituted by the first number of signaling-link interconnects and the second number of the signaling-link interconnects.

8. The memory controller of claim 1 wherein each signaling-link interconnect of the plurality of signaling-link interconnects includes a respective output driver, and wherein at least each signaling-link interconnect of the third number of signaling-link interconnects includes a signal receiver.

9. The memory controller of claim 1 wherein the configuration logic to allocate the second number of the signaling-link interconnects to the command/address signaling function and to allocate the third number of the signaling-link interconnects to the data signaling function comprises circuitry to enable a portion of the plurality of signaling-link interconnects to output differential command/address signals in the first interface configuration and to enable the portion of the plurality of signaling-link interconnects to output differential data signals in the second interface configuration.

10. The memory controller of claim 1 wherein the first interface configuration corresponds to a signaling interface within a memory component of a first type, and the second interface configuration corresponds to a signaling interface within a second memory type.

11. The memory controller of claim 1 wherein the configuration logic to allocate the first number of the signaling-link interconnects to the data signaling function and the second number of the signaling-link interconnects to the command/address signaling function comprises circuitry to enable (i) transmission of memory write commands, memory read commands and corresponding address values to a memory component via the second number of the signaling-link interconnects, (ii) transmission of write-data, associated with the memory write commands, to be stored within the memory component via the first number of the signaling-link interconnects and (iii) reception of read data, associated with the memory read commands, via the first number of the signaling-link interconnects.

12. A method of operation within a memory controller having a plurality of signaling-link interconnects to be connected to respective external signaling links, the method comprising:
allocating a first number of the signaling-link interconnects to a data signaling function and a second number of the signaling-link interconnects to a command/address signaling function in a first interface configuration; and
allocating a third number of the signaling-link interconnects to the data signaling function and a fourth number of the signaling-link interconnects to the command/address signaling function in a second interface configuration, the third number of the signaling-link interconnects being greater than the total number of signaling-link interconnects minus the second number of signaling-link interconnects.

13. The method of claim 12 wherein allocating the first number of the signaling-link interconnects to a data signaling function in the first interface configuration comprises enabling at least a portion of the first number of the signaling-link interconnects to output a corresponding number of single-ended write-data signals onto respective single-ended signaling links, and wherein allocating the third number of the signaling-link interconnects to a data signaling function in the second interface configuration comprises enabling at least a portion of the third number of the signaling-link interconnects to output a fifth number of differential write-data signals onto respective differential signaling links.

14. The method of claim 12 wherein allocating the second number of signaling-link interconnects to the command/address signaling function in the first interface configuration comprises limiting the second number of signaling-link interconnects to uni-directional signaling, and wherein allocating the third number of signaling-link interconnects to the data signaling function in the second interface configuration comprises enabling at least a portion of the second number of signaling-links to bi-directionally transmit write-data and receive read data.

15. The method of claim 12 wherein allocating the first number of the signaling-link interconnects to the data signaling function and the second number of the signaling-link interconnects to the command/address signaling function in the first interface configuration comprises allocating the first number of the signaling-link interconnects to the data signaling function and the second number of the signaling-link interconnects to the command/address signaling function if an interface mode value within a storage register of the memory controller indicates a first memory interface type, and wherein allocating the third number of the signaling-link interconnects to the data signaling function and the fourth number of the signaling-link interconnects to the command/address signaling function in a second interface configuration comprises allocating the third number of the signaling-link interconnects to the data signaling function and the fourth number of the signaling-link interconnects to the command/address signaling function if the interface mode value within the storage register indicates a second memory interface type.

16. The method of claim 12 further comprising receiving a value that indicates one of a plurality of memory interface types and storing the value within a programmable register of the memory controller to select one of a plurality of interface configurations supported within the memory controller, the plurality of interface configurations including at least the first interface configuration and the second interface configuration.

17. The method of claim 12 wherein the third number of signaling-link interconnects and the fourth number of signaling-link interconnects collectively constitute more signaling-link interconnects than collectively constituted by the first number of signaling-link interconnects and the second number of the signaling-link interconnects

18. The method of claim 12 further comprising allocating a fifth number of the signaling-link interconnects to the data signaling function and a sixth number of the signaling-link interconnects to the command/address signaling function in a third interface configuration, wherein the third number of the signaling-link interconnects is greater than the total number of signaling-link interconnects minus the fifth number of signaling-link interconnects.

19. The method of claim 18 wherein the fifth number of signaling-link interconnects and the sixth number of signaling-link interconnects collectively constitute more signaling-link interconnects than collectively constituted by the first number of signaling-link interconnects and the second number of the signaling-link interconnects.

20. The method of claim 12 wherein each signaling-link interconnect of the plurality of signaling-link interconnects includes a respective output driver, and wherein at least each signaling-link interconnect of the third number of signaling-link interconnects includes a signal receiver.

21. The method of claim 12 wherein allocating the second number of the signaling-link interconnects to the command/address signaling function in the first interface configuration comprises enabling a portion of the plurality of signaling-link interconnects to output differential command/address signals, and wherein allocating the third number of the signaling-link interconnects to the data signaling function in the second interface configuration comprises enabling the portion of the plurality of signaling-link interconnects to output differential data signals.

22. The method of claim 12 wherein the first interface configuration corresponds to a signaling interface within a memory component of a first type, and the second interface configuration corresponds to a signaling interface within a second memory type.

23. The method of claim 12 wherein allocating the first number of the signaling-link interconnects to the data signaling function and the second number of the signaling-link interconnects to a command/address signaling function in the first interface configuration comprises:
enabling transmission of memory write commands, memory read commands and corresponding address values to a memory component via the second number of the signaling-link interconnects;
enabling transmission of write-data, associated with the memory write commands, to be stored within the memory component via the first number of the signaling-link interconnects; and
enabling reception of read data, associated with the memory read commands, via the first number of the signaling-link interconnects.

24. A memory controller comprising:
a plurality of signaling-link interconnects to be connected to respective external signaling links; and
means for allocating a first number of the signaling-link interconnects to a data signaling function and a second number of the signaling-link interconnects to a command/address signaling function in a first interface configuration, and for allocating a third number of the signaling-link interconnects to the data signaling function and a fourth number of the signaling-link interconnects to the command/address signaling function in a second interface configuration, the third number of the signaling-link interconnects being greater than the total number of signaling-link interconnects minus the second number of signaling-link interconnects.
